(19) United States
(12) Patent Application Publication
(10) Pub. No.: US 2017/0287564 A1
(43) Pub. Date: Oct. 5, 2017

(54) MEMORY SYSTEM AND OPERATING METHOD THEREOF

(71) Applicant: SK hynix Inc., Gyeonggi-do (KR)

(72) Inventors: Byoung Jun PARK, Chungcheongbuk-do (KR); Seong Jo PARK, Chungcheongnam-do (KR)

(21) Appl. No.: 15/222,593

(22) Filed: Jul. 28, 2016

(30) Foreign Application Priority Data
Mar. 29, 2016 (KR) 10-2016-0037526

(51) Int. Cl. G11C 16/26; G06F 11/10; G11C 16/08; G06F 3/06; G11C 16/16; G11C 16/10; G11C 15/04; G11C 29/52

(52) U.S. Cl. CPC G11C 16/26; G11C 15/046; G06F 11/1068; G06F 11/1064; G11C 29/52; G06F 3/0619; G06F 3/064; G06F 3/0679; G11C 16/16; G11C 16/10; G11C 16/08

(57) ABSTRACT

The present disclosure relates to a memory system and an operating method thereof. A memory system may include a semiconductor memory device including a cam block and a normal memory block, and a controller suitable for setting an initial setting read voltage according to an option parameter stored in the cam block and controlling the semiconductor memory device to perform a first read operation to the normal memory block according to the initial setting read voltage.

### CROSS-REFERENCE TO RELATED APPLICATION

The present application claims priority under 35 U.S.C. §119(a) to Korean patent application number 10-2016-0037526, filed on Mar. 29, 2016, the entire disclosure of which is herein incorporated by reference in its entirety.

### BACKGROUND

### Field of Invention

Various embodiments of the invention relate generally to an electronic device, and more particularly, to a memory system and an operating method thereof.

### Description of Related Art

Semiconductor memory devices may be classified into volatile memory devices and non-volatile memory devices.

Non-volatile memory devices operate at relatively low write and read speeds than volatile memory devices, but they retain the stored data regardless of power on/off conditions. Therefore, non-volatile memory devices are used to store data which need to be maintained even in the absence of power supply. Examples of non-volatile memory include read only memory (ROM), mask ROM (MROM), programmable ROM (PROM), erasable programmable ROM (EPROM), electrically erasable and programmable ROM (EEPROM), flash memory, Phase-change random access memory (PRAM), magnetic RAM (MRAM), resistive RAM (RRAM) and ferroelectric RAM (FRAM). Flash memories may be classified into NOR- or NAND-type memories.

Flash memories enjoy the advantages of both RAM and ROM devices. For example, flash memories may be freely programmed and erased similar to a RAM. Also, similar to a ROM, flash memories may retain the stored data even when they are not powered. Flash memories have been widely used as the storage media of portable electronic devices such as mobile phones, digital cameras, personal digital assistants (PDAs), and MP3 players.

### SUMMARY

Various embodiments are directed to a memory system with improved reliability and performance for a read operation and an operating method thereof.

According to an embodiment, a memory system may include a semiconductor memory device including a cam block and a normal memory block, and a controller suitable for setting an initial setting read voltage according to an option parameter stored in the cam block and controlling the semiconductor memory device to perform a first read operation to the normal memory block according to the initial setting read voltage.

According to an embodiment, a memory system may include a semiconductor memory device including a cam block and a normal memory block, and a controller suitable for setting an initial setting read voltage according to an option parameter stored in the cam block and a plurality of initial setting read voltage indexes and controlling the semiconductor memory device to perform a first read operation to the normal memory block according to the initial setting read voltage.

According to an embodiment, a method of operating a memory system may include providing a semiconductor memory device including a cam block and a normal memory block and a controller suitable for controlling a read operation of the semiconductor memory device, setting an initial setting read voltage according to an option parameter stored in the cam block when a read request is input to the controller, performing a first read operation according to the initial setting read voltage, and performing a second read operation according to a read retry scheme when a number of fail bits included in data read as a result of the first read operation is greater than a maximum number of allowable error bits.

### BRIEF DESCRIPTION OF THE DRAWINGS

FIG. 1 is a block diagram illustrating a block diagram illustrating a memory system according to an embodiment;

FIG. 2 is a block diagram illustrating a semiconductor memory device of FIG. 1;

FIG. 3 is a block diagram illustrating an embodiment of a memory cell array of FIG. 2;

FIG. 4 is a three-dimensional view illustrating a memory string included in a memory block;

FIG. 5 is a circuit diagram illustrating a memory string of FIG. 4;

FIG. 6 is a flowchart illustrating a method of operating a memory system according to an embodiment;

FIG. 7 is a block diagram illustrating an application example of a memory system of FIG. 6; and

FIG. 8 is a block diagram illustrating a computing system including a memory system described with reference to FIG. 7.

### DETAILED DESCRIPTION

Various embodiments may relate to a semiconductor memory device having improved reliability and an operating method thereof. Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

It should be understood that, when it is described that an element is “coupled” or “connected” to another element, the element may be directly coupled or directly connected to the other element or coupled or connected to the other element through a third element. On the contrary, it should be understood that when an element is referred to as being “directly connected to” or “directly coupled to” another element, another element does not intervene therebetween. Other expressions which describe the relationship between components, that is, “between” and “directly between”, or “adjacent to” and “directly adjacent to” need to be interpreted by the same manner.

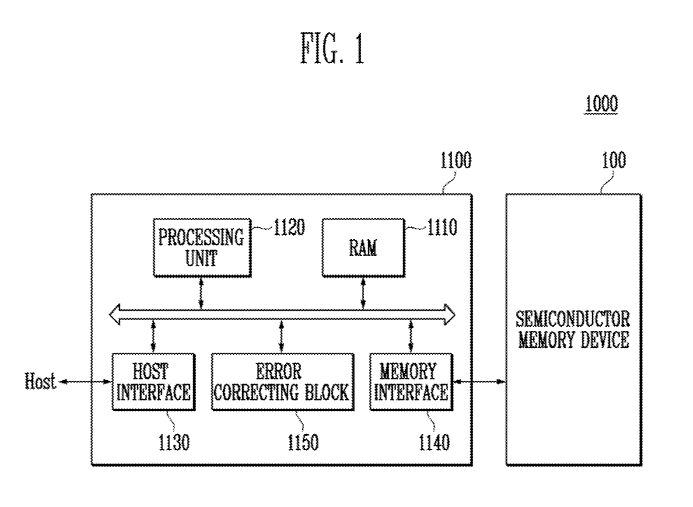

FIG. 1 is a block diagram illustrating a memory system 1000 according to an embodiment.

Referring to FIG. 1, the memory system 1000 may include a semiconductor memory device 100 and a controller 1100.

The controller 1100 may be coupled to a host and the semiconductor memory device 100. The controller 1100 may be configured to access the semiconductor memory device 100 at the request of the host. For example, the controller 1100 may control a read operation, a program operation, an erase operation, and/or a background operation of the semiconductor memory device 100. The controller 1100 may provide an interface between the semiconductor memory device 100 and the host. The controller 1100 may drive firmware for controlling the semiconductor memory device 100.

According to an embodiment, when a read request is input from the host, the controller 1100 may select one of a plurality of initial setting read voltage indexes according to an option parameter stored in the semiconductor memory device 100 and may control the semiconductor memory device 100 to perform a first read operation. The plurality of initial setting read voltage indexes may be included in firmware, or stored in the semiconductor memory device 100. In addition, when the controller 1100 determines that a number of fail bits included in read data as a result of the first read operation is greater than a maximum ECC bit number, the controller 1100 may control the semiconductor memory device 100 to perform a second read operation according to a read retry scheme. The option parameter may include temperature information of the semiconductor memory device 100, time information about the last performed read operation, read count information, etc.

The controller 1100 may include a random access memory (RAM) 1110, a processing unit 1120, a host interface 1130, a memory interface 1140, and an error correcting block 1150.

The RAM 1110 may include firmware and be used as an operation memory, a cache memory between the memory device 1200 and the host, and a buffer memory between the memory device 1200 and the host. The firmware may include an algorithm for performing operations and a plurality of initial setting read voltage indices. According to an embodiment, the firmware may be stored in the RAM 1110. However, the controller 1100 may be configured to include read only memory (ROM).

The processing unit 1120 may control general operations of the controller 1100. The processing unit 1120 may control the semiconductor memory device 100 to control a read voltage of a second read operation through repeated read operations with the read voltage gradually varying according to an error detection result of the error correcting block 1150 and a read retry table.

The host interface 1130 may include a protocol for exchanging data between the host and the controller 1100. For example, the controller 1100 may communicate with the host through one or more various protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a private protocol, etc.

The memory interface 1140 may interface with the semiconductor memory device 100. For example, the memory interface may include a NAND flash interface or a NOR flash interface.

The error correcting block 1150 may detect and correct errors in data read from the semiconductor memory device 100 by using an error correction code (ECC). For example, the error correcting block 1150 may compare the number of detected error bits with a maximum number of allowable error bits, and correct the detected error bits when the number of the detected error bits is less than the maximum number of allowable error bits.

The controller 1100 and the semiconductor memory device 100 may be integrated in a single semiconductor device. According to an embodiment, the controller 1100 and the semiconductor memory device 100 may be integrated in a single semiconductor device to form a memory card such as a PC card (personal computer memory card international association (PCMCIA)), a compact flash card (CF), a smart media card (SMC), a memory stick, a multimedia card (MMC, RS-MMC or MMCmicro), an SD card (SD, miniSD, micro SD or SDHC), a universal flash storage device (UFS), etc.

The controller 1100 and the semiconductor memory device 100 may be integrated in a single semiconductor device to form a solid state drive (SSD). The SSD may include a storage device for storing data in a semiconductor memory device. When the memory system 1000 is used as an SSD, operational rates of the host coupled to the memory system 1000 may be significantly improved.

In another example, the memory system 1000 may be used as one of several elements in various electronic devices such as a computer, an ultra mobile PC (UMPC), a workstation, a net-book, a personal digital assistant (PDA), a portable computer, a web table, a wireless phone, a mobile phone, a smart phone, an e-book, a portable multimedia player (PMP), a portable game machine, a navigation device, a black box, a digital camera, a three-dimensional television, a digital audio recorder, a digital audio player, a digital picture recorder, a digital picture player, a digital video recorder, a digital video player, a device for transmitting/receiving information in wireless environments, devices for home networks, devices for computer networks, devices for telematics networks, an RFID device, other devices for computing systems, etc.

According to an exemplary embodiment, the semiconductor memory device 100 or the memory system 1000 may be packaged in various forms. For example, the semiconductor memory device 100 or the memory system 1000 may be packaged by various methods such as a package on package (PoP), a ball grid array (BGA), a chip scale package (CSP), a plastic leaded chip carrier (PLCC), a plastic dual in line package (PDIP), a die in waffle pack, a die in wafer form, a chip on board (COB), a ceramic dual in line package (CERDIP), a plastic metric quad flat package (MQFP), a thin quad flat package (TQFP), a small outline integrated circuit (SOIC), a shrink small outline package (SSOP), a thin small outline package (TSOP), a system in package (SIP), a multi chip package (MCP), a wafer-level fabricated package (WFP), a wafer-level processed stack package (WSP), etc.

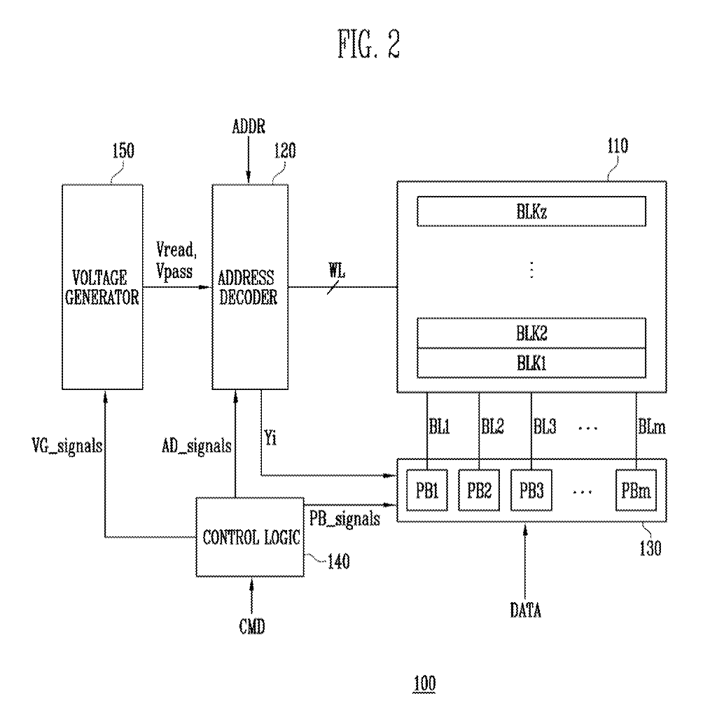

FIG. 2 is a block diagram illustrating a semiconductor memory device of FIG. 1.

Referring to FIG. 2, the semiconductor memory device 100 may include a memory cell array 110, an address decoder 120, a read and write circuit 130, a control logic 140, and a voltage generator 150.

The address decoder 120, the read and write circuit 130 and the voltage generator 150 may be defined as a peripheral circuit configured to perform a read operation on the memory cell array 110.

The memory cell array 110 may include a plurality of memory blocks BLK1 to BLKz. The memory blocks BLK1 to BLKz may be coupled to the address decoder 120 through word lines WL. The memory blocks BLK1 to BLKz may be coupled to the read and write circuit 130 through bit lines BL1 to BLm. Each of the memory blocks BLK1 to BLKz may include a plurality of memory cells. According to an embodiment, the plurality of memory cells may be non-volatile memory cells. More specifically, the plurality of memory cells may be non-volatile memory cells based on a charge trap device. A plurality of memory cells connected in common to the same word line may be defined as a single page. The memory cell array 110 may include a plurality of pages. In addition, each of the memory blocks BLK1 to BLKz of the memory cell array 110 may include a plurality of strings. Each of the strings may include a drain selection transistor, a plurality of memory cells and a source selection transistor coupled in series between a bit line and a source line.

According to an embodiment, at least one (e.g., the memory block BLKz) of the plurality of memory blocks BLK1 to BLKz may serve as a content addressed memory (CAM) block for storing data about an option parameter with respect to the semiconductor memory device 100, data about initial setting read voltage indices and data about a read retry table, and the remaining memory blocks BLK1 to BLKz−1 may serve as normal memory blocks. When the data about the plurality of initial setting read voltage indexes are included in the firmware stored in the controller 1100 of FIG. 1, the data about the option parameter and the data about the read retry table may be stored in the cam block BLKz.

The address decoder 120 may be coupled to the memory cell array 110 through the word lines WL. The address decoder 120 may be configured to operate in response to control signals AD_signals output from the control logic 140. The address decoder 120 may receive an address ADDR through an input/output buffer (not illustrated) in the semiconductor memory device 100.

The address decoder 120 may apply the read voltage Vread and the pass voltage Vpass generated by the voltage generator 150 to the word lines WL of the memory cell array 110 during the read operation.

A read operation of the semiconductor memory device 100 may be performed by selecting at least one of the memory blocks BLK1 to BLKz. In addition, the read operation of the selected memory block may be performed in units of pages.

The address ADDR received in response to a request for a read operation may include a block address, a row address and a column address. The address decoder 120 may select one memory block and one word line in response to the block address and the row address. The column address (Yi) may be decoded by the address decoder 120 and provided to the read and write circuit 130.

The address decoder 120 may include a block decoder, a row decoder, a column decoder and an address buffer.

The read and write circuit 130 may include a plurality of page buffers PB1 to PBm. The page buffers PB1 to PBm may be coupled to the memory cell array 110 through the bit lines BL1 to BLm. Each of the page buffers PB1 to PBm may perform a read operation by sensing a potential level or a current amount of each of the bit lines BL1 to BLm corresponding thereto during the read operation.

The control logic 140 may be coupled to the address decoder 120, the read and write circuit 130, and the voltage generator 150. The control logic 140 may receive a command CMD through an input/output buffer (not illustrated) of the semiconductor memory device 100. The control logic 140 may be configured to control the general operations of the semiconductor memory device 100 in response to the command CMD.

In response to the command CMD for an erase operation of all memory blocks, the control logic 140 may control the address decoder 120, the read and write circuit 130, and the voltage generator 150 to read the data about the option parameter and the data about the initial setting read voltage indexes from the cam block BLKz, and output the read data to the controller 1100 of FIG. 1. Subsequently, the control logic 140 may set the read voltage Vread in response to the command CMD for the first read operation and the information about an initial setting read voltage, which are provided from the controller 1100, and may control the address decoder 120, the read and write circuit 130, and the voltage generator 150 to perform the first read operation according to the set read voltage Vread. In addition, in response to the command CMD for a second read operation provided from the controller 1100, the control logic 140 may control the address decoder 120, the read and write circuit 130, and the voltage generator 150 to repeat a read operation by gradually changing the read voltage Vread according to the read retry table stored in the cam block BLKz.

The voltage generator 150 may operate in response to the control signals VG_signals output from the control logic 140. For example, the voltage generator 150 may generate the program voltage Vpgm and the pass voltage Vpass in response to the control logic 140 during the read operation.

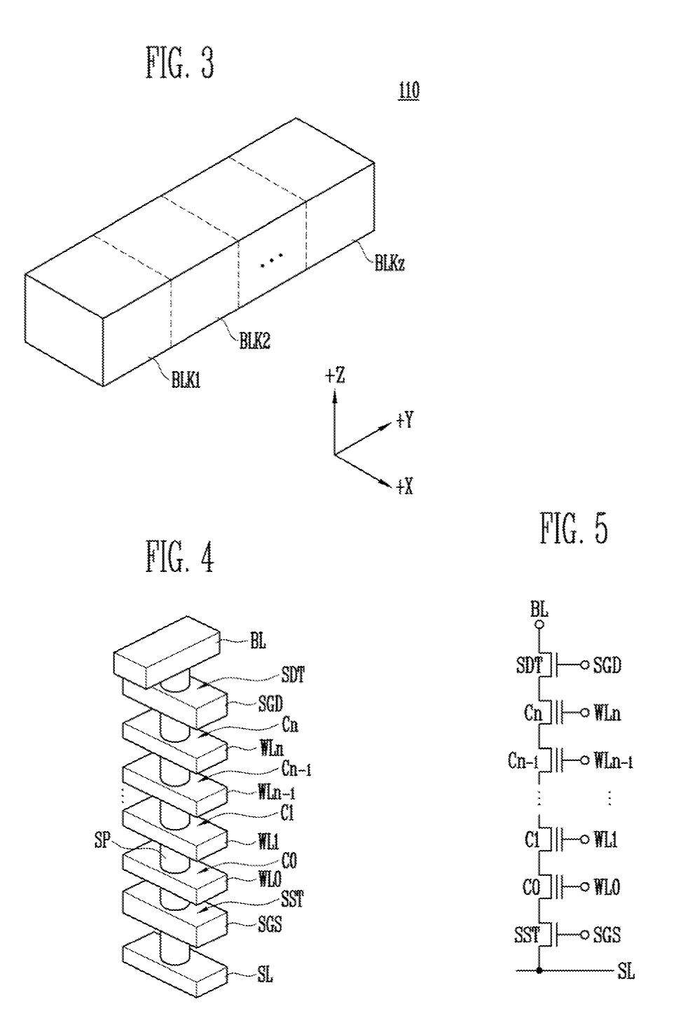

FIG. 3 is a block diagram illustrating an embodiment of the memory cell array 110 of FIG. 1.

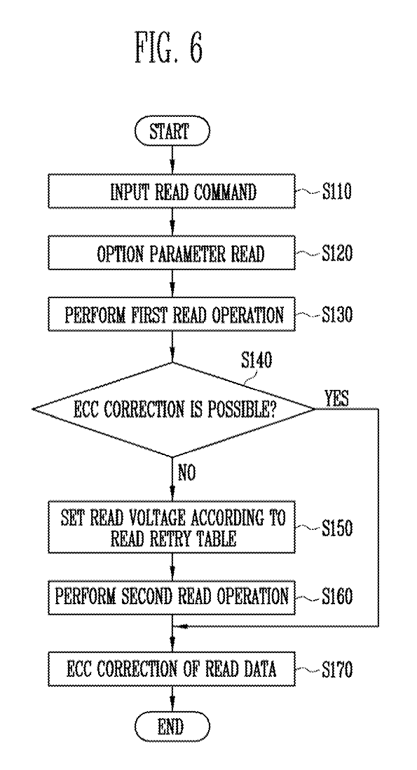

Referring to FIG. 3, the memory cell array 110 may include the plurality of memory blocks BLK1 to BLKz. Each of the plurality of memory blocks BLK1 to BLKz may have a three-dimensional structure. Each of the memory blocks may include a plurality of memory cells stacked over a substrate. The plurality of memory cells may be arranged in +X direction, +Y direction and +Z direction. Each of the memory blocks BLK1 to BLKz will be described in more detail with reference to FIGS. 4 and 5.

FIG. 4 is a three-dimensional view illustrating a memory string included in a memory block according to an embodiment. FIG. 5 is a circuit diagram illustrating a memory string.

Referring to FIGS. 4 and 5, a source line SL may be formed over a semiconductor substrate. A vertical channel layer SP may be formed on the source line SL. A top portion of the vertical channel layer SP may be coupled to the bit line BL. The vertical channel layer SP may include polysilicon. A plurality of conductive layers SGS, WL0 to WLn, and SGD may be formed to surround the vertical channel layer SP at different heights. A multilayer film (not illustrated) including a charge storage layer may be formed on the surface of the vertical channel layer SP. The multilayer film may be located between the vertical channel layer SP and the conductive layers SGS, WL0 to WLn, and SGD. The multilayer film may have an ONO structure in which an oxide layer, a nitride layer and an oxide layer are sequentially stacked.

The lowermost conductive layer may be a source selection line (or first selection line) SGS, and the uppermost conductive layer may be a drain selection line (or second selection line) SGD. Conductive layers between the selection lines SGS and SGD may be word lines WL0 to WLn. In other words, the conductive layers SGS, WL0 to WLn, and SGD may include a plurality of layers formed over the semiconductor substrate. The vertical channel layer SP passing through the conductive layers SGS, WL0 to WLn, and SGD may be coupled in a vertical direction between the bit line BL and the source line SL formed on the semiconductor substrate.

A drain selection transistor SDT may be formed at a portion where the uppermost conductive layer SGD surrounds the vertical channel layer SP. A source selection transistor SST may be formed at a portion where the lowermost conductive layer SGS surrounds the vertical channel layer SP. Memory cells C0 to Cn may be formed at portions where intermediate conductive layers WL0 to WLn surround the vertical channel layer SP.

The memory string having the above-described structure may include the source selection transistor SST, the memory cells C0 to Cn and the drain selection transistor SDT that are coupled in the vertical direction to the substrate between the source line SL and the bit line BL. The source selection transistor SST may electrically couple the memory cells C0 to Cn to the source line SL in response to a first selection signal applied to the first selection line SGS. The drain selection transistor SDT may electrically couple the memory cells C0 to Cn to the bit line BL in response to a second selection signal applied to the second selection line SGD.

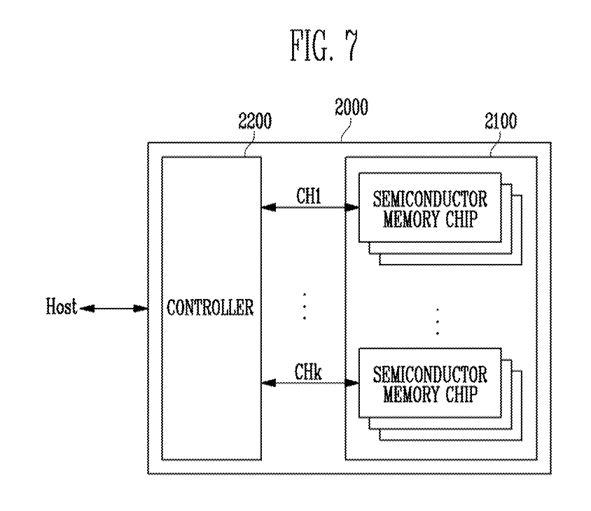

FIG. 6 is a flowchart illustrating a method of operating a memory system according to an embodiment.

A method of operating a memory device according to an embodiment will be described below with reference to FIGS. 1 to 6. An example in which initial setting read voltage indexes are stored in the controller 110 will be described as follows.

At step S110, when a read request is input from the host, the controller 1100 may output a command CMD for the read operation to the semiconductor memory device 100.

At step S120, the control logic 140 of the semiconductor memory device 100 may control the address decoder 120, the read and write circuit 130, and the voltage generator 150 to read the data about the option parameter stored in the cam block BLKz of the memory cell array 110 and output the read data to the controller 1100.

The processing unit 1120 of the controller 1100 may select one of the plurality of initial setting read voltage indexes stored in the RAM 1110 according to the data about the option parameter provided from the semiconductor memory device 100, and output information about an initial setting read voltage to the semiconductor memory device 100. The initial setting read voltage may be set such that the number of error bits included in a read data during the first read operation according to the initial setting read voltage is be less than the maximum number of allowable error bits of the error correcting block 1150. For example, the processing unit 1120 may select an optimal one among the plurality of initial setting read voltage indexes according to temperature information, time information about the last performed read operation, read count information, etc. included in the information about the option parameter provided from the semiconductor memory device 100, and output the information about the initial setting read voltage to the semiconductor memory device 100 according to the selected initial setting read voltage index.

At step S130, the control logic 140 may receive the command CMD for the first read operation and the information about the initial setting read voltage from the controller 1100, and control the address decoder 120, the read and write circuit 130, and the voltage generator 150 to set the read voltage Vread based on the provided information about the initial setting read voltage and to perform the first read operation according to the set read voltage Vread. In addition, data read as a result of the first read operation may be output to the controller 1100.

At step S140, the error correcting block 1150 of the controller 1100 may detect an error in the read data of the first read operation provided from the semiconductor memory device 100 and compare the number of bits of the detected error with a maximum number of allowable error bits to determine whether ECC correction is possible.

When it is determined that the ECC correction is possible at S140, the error correcting block 1150 may correct errors in the read data by using the ECC and output the error-corrected data to the host at step S170.

A threshold voltage distribution of the memory cells included in the memory cell array 110 of the semiconductor memory device 100 may be increased or decreased according to retention characteristics. Therefore, as a specific cycling and storage time passes, error bits of the data read by the first read operation using the initial setting read voltage may be increased. Thus, the semiconductor memory device 100 may determine that the ECC correction is impossible as a result of the determination at S140.

When it is determined that it is impossible to perform the ECC correction of the data read as the result of the first read operation at S140, the controller 1100 may control the semiconductor memory device 100 to set the read voltage according to the read retry table at step S150.

Step S150 is described below in more detail.

The control logic 140 may read the read retry table stored in the cam block BLKz and control the address decoder 120, the read and write circuit 130, and the voltage generator 150 to repeat a read operation by gradually increasing or decreasing the read voltage Vread according to the read retry table. The processing unit 1120 may control the semiconductor memory device 100 to control a read voltage of the second read operation through the repeated read operations with the gradually increased or decreased read voltage according to an error detection result of the error correcting block 1150 and the read retry table. The processing unit 1120 may control the semiconductor memory device 100 to perform the second read operation by setting the read voltage, with which the smallest number of error bits is detected during the repeated read operations with gradual variation of the read voltage, as the read voltage Vread for the second read operation.

At step S160, the control logic 140 may control the address decoder 120, the read and write circuit 130, and the voltage generator 150 to perform the second read operation according to the read voltage Vread set at step S150. The control logic 140 may output read data read as a result of the second read operation to the controller 1100.

At step S170, the error correcting block 1150 may correct errors in the read data by using an error correction code and output the error-corrected read data to the host.

According to the above-described embodiment, since the first read operation precedes the second read operation, frequency in use of the read retry table during the second read operation may be reduced to improve read performance and reliability of the memory system may be improved.

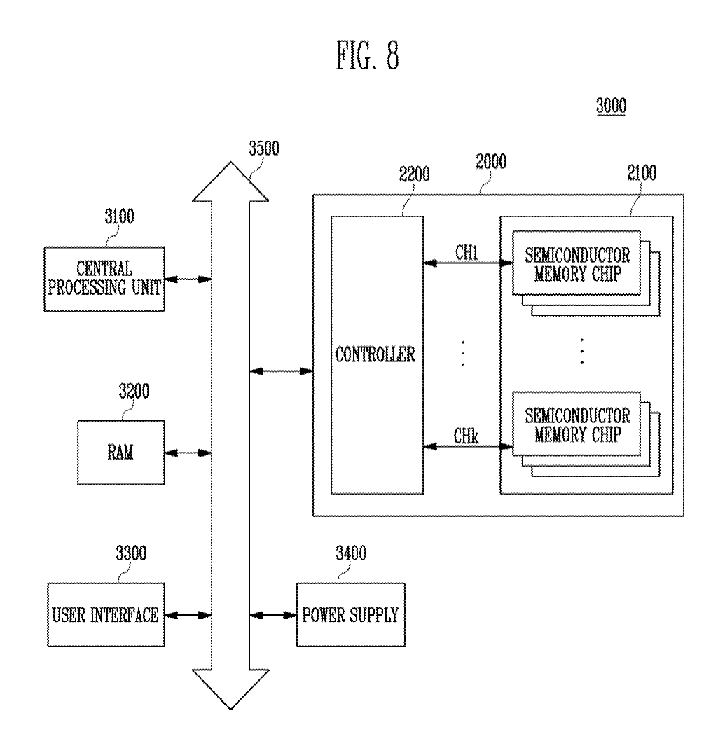

FIG. 7 is a block diagram illustrating an application example (2000) of the memory system 1000 of FIG. 1.

Referring to FIG. 7, a memory system 2000 may include a semiconductor memory device 2100 and a controller 2200. The semiconductor memory device 2100 may include a plurality of semiconductor memory chips. The plurality of semiconductor memory chips may be divided into groups.

FIG. 7 illustrates the plurality of groups communicating with the controller 2200 through first to k-th channels CH1 to CHk. Each of the semiconductor memory chips may be configured and operated in substantially the same manner as one of the semiconductor memory devices 100 described above with reference to FIG. 2.

Each group may communicate with the controller 2200 through a single common channel. The controller 2200 may be configured in substantially the same manner as the controller 1100 described with reference to FIG. 1, and configured to control the plurality of memory chips of the semiconductor memory device 2100 through the plurality of first to k-th channels CH1 to CHk.

FIG. 8 is a block diagram illustrating a computing system 3000 having the memory system described above with reference to FIG. 7.

Referring to FIG. 8, the computing system 3000 may include a central processing unit 3100, a random access memory (RAM) 3200, a user interface 3300, a power supply 3400, a system bus 3500, and the memory system 2000.

The memory system 2000 may be electrically connected to the central processing unit 3100, the RAM 3200, the user interface 3300 and the power supply 3400 through the system bus 3500. Data provided through the user interface 3300 or processed by the central processing unit 3100 may be stored in the memory system 2000.

As illustrated in FIG. 8, the semiconductor memory device 2100 may be coupled to the system bus 3500 through the controller 2200. However, the semiconductor memory device 2100 may be directly coupled to the system bus 3500. The central processing unit 3100 and the RAM 3200 may perform the functions of the controller 2200.

As illustrated in FIG. 8, the memory system 2000 described with reference to FIG. 7 may be provided. However, the memory system 2000 may be replaced with the memory system 1000 described above with reference to FIG. 1. According to an embodiment, the computing system 3000 may include both of the memory systems 1000 and 2000 described above with reference to FIGS. 6 and 7, respectively.

According to embodiments, reliability of a read operation may be improved by performing the read operation in consideration of retention characteristics of memory cells during a read operation of a memory system.

It will be apparent to those skilled in the art that various modifications can be made to the above-described exemplary embodiments of the present invention without departing from the spirit or scope of the invention. Thus, it is intended that the present invention cover all such modifications provided they come within the scope of the appended claims and their equivalents.

What is claimed is:

1. A memory system, comprising:
a semiconductor memory device including a cam block and a normal memory block; and
a controller suitable for setting an initial setting read voltage according to an option parameter stored in the cam block, and controlling the semiconductor memory device to perform a first read operation to the normal memory block according to the initial setting read voltage.

2. The memory system of claim 1, wherein the option parameter includes temperature information of the semiconductor memory device, time information of a last performed read operation, and read count information.

3. The memory system of claim 1,
wherein the controller sets the initial setting read voltage by selecting one among a plurality of initial setting read voltage indexes, and
wherein the initial setting read voltage is set such that a number of error bits included in data read as a result of the first read operation is less than a maximum number of allowable error bits.

4. The memory system of claim 1, wherein the controller controls the semiconductor memory device to perform a second read operation according to a read retry scheme when a number of fail bits included in data read as a result of the first read operation is greater than a maximum number of allowable error bits.

5. The memory system of claim 4, wherein the second read operation is performed to the normal memory block according to a read voltage, with which a smallest number of error bits is detected while repeating a read operation to the normal memory block with gradual variation of the read voltage.

6. The memory system of claim 4, wherein the semiconductor memory device comprises:
a memory cell array including the cam block and the normal memory block;
a peripheral circuit suitable for performing a read operation to the normal memory block; and
a control logic suitable for controlling the peripheral circuit to read the option parameter stored in the cam block, and output the option parameter to the controller.

7. The memory system of claim 6, wherein the control logic controls the peripheral circuit to perform the first read operation to the normal memory block according to the initial setting read voltage.

8. The memory system of claim 4, wherein the controller comprises:
random access memory (RAM) suitable for storing firmware;
an error correcting block suitable for detecting an error bit of data read from the semiconductor memory device, and correcting a detected error bit; and
a processing unit suitable for controlling the semiconductor memory device to repeat a read operation to the normal memory block with gradual variation of the read voltage according to a read retry table and to control a read voltage of the second read operation according to an error detection result of the error correcting block when the number of fail bits included in data read as a result of the first read operation is greater than the maximum number of allowable error bits.

9. The memory system of claim 8, wherein the firmware includes a plurality of initial setting read voltage indexes.

10. The memory system of claim 9, wherein the processing unit selects one among the initial setting read voltage indexes according to the option parameter, and sets the initial setting read voltage according to the selected initial setting read voltage index.

11. A memory system, comprising:
a semiconductor memory device including a cam block and a normal memory block; and
a controller suitable for setting an initial setting read voltage according to an option parameter stored in the cam block and a plurality of initial setting read voltage indexes, and controlling the semiconductor memory device to perform a first read operation to the normal memory block according to the initial setting read voltage.

12. The memory system of claim 11, wherein the option parameter includes temperature information of the semiconductor memory device, time information of a last performed read operation, and read count information.

13. The memory system of claim 11, wherein the controller sets the initial setting read voltage by selecting one among the plurality of initial setting read voltage indexes according to the option parameter.

14. The memory system of claim 13, wherein the controller sets the initial setting read voltage such that a number of error bits included in data read as a result of the first read operation is less than a maximum number of allowable error bits.

15. The memory system of claim 14, wherein the controller controls the semiconductor memory device to perform a second read operation according to a read retry scheme when a number of fail bits included in data read as the result of the first read operation is greater than a maximum number of allowable error bits.

16. The memory system of claim 15, wherein the second read operation is performed to the normal memory block according to a read voltage, with which a smallest number of error bits is detected while repeating a read operation to the normal memory block with gradual variation of the read voltage.

17. A method of operating a memory system including a semiconductor memory device including a cam block and a normal memory block and a controller controlling a read operation of the semiconductor memory device, the method comprising:
setting an initial setting read voltage according to an option parameter stored in the cam block when a read request is input to the controller;
performing a first read operation according to the initial setting read voltage; and
performing a second read operation according to a read retry scheme when a number of fail bits included in data read as a result of the first read operation is greater than a maximum number of allowable error bits.

18. The method of claim 17, wherein the option parameter includes temperature information of the semiconductor memory device, time information of a last performed read operation, and read count information.

19. The method of claim 17,
wherein the setting of the initial setting read voltage comprises setting the initial setting read voltage by selecting one among a plurality of initial setting read voltage indexes stored in the controller or the cam block, and
wherein the initial setting read voltage is set according to the option parameter such that a number of error bits included in data read as a result of the first read operation is less than a maximum number of allowable error bits.

20. The method of claim 17, wherein the second read operation is performed to the normal memory block according to a read voltage, with which a smallest number of error bits is detected while repeating a read operation to the normal memory block with gradual variation of the read voltage.
